(19) United States
(12) Patent Application Publication
(10) Pub. No.: US 2011/0241789 A1
(43) Pub. Date: Oct. 6, 2011

(54) INTEGRATED CIRCUIT CAPABLE OF REPEATEDLY USING CURRENT

(75) Inventors: Wei-Sung Chang, Pingjhen City (TW); Shuo-Hung Hsu, Hsinchu City (TW)

(73) Assignee: NATIONAL TSING HUA UNIVERSITY (TAIWAN), Hsinchu (TW)

(21) Appl. No.: 12/885,494

(22) Filed: Sep. 18, 2010

(30) Foreign Application Priority Data
Apr. 1, 2010 (TW) 099110148

(51) Int. Cl. H03B 5/12

(52) U.S. Cl. 331/117 FE

(57) ABSTRACT

The invention relates to an integrated circuit capable of repeatedly using current, the integrated circuit comprises: a first differential input, a first cross couple pair, a second differential input, a second cross couple pair, and a voltage-controlled oscillator, wherein a divider consists of the first differential input, the first cross couple pair, the second differential input, and the second cross couple pair, moreover, through the connection of the first differential input, the first cross couple pair, the second differential input, and the second cross couple pair, the divider and the voltage-controlled oscillator may be drove by only one single current, so that the circuit area, the power consumption, and the phase noise of the integrated circuit are simultaneously reduced.

### BACKGROUND OF THE INVENTION

1. Technical Field

The present invention relates to an integrated circuit of an oscillator and a divider, and more particularly, to an integrated circuit capable of repeatedly using current which has the reduced circuit area and low power consumption.

2. Description of Related Art

With the development of the Internet, demands of the data transmission speed and the data transmission capacity are increasing. For this reason, an optical communication system using a fiber as a data transmission medium is extensively used in each of levels of the Internet Network. The main transmission format of the optical communication system is OC-48 (2.5 Gb/s), furthermore, in next generation, the developing targets of the transmission format are OC-192 (10 Gb/s) and OC-768 (40 Gb/s).

Referring to FIG. 1, a framework diagram of a conventional optical communication system is illustrated. As shown in FIG. 1, the conventional optical communication system 1′ includes: a transmitting interface 11′, a fiber 12′ and a receiving interface 13′, wherein data are processed and transformed by a first digital circuit 111′, a multiplexer 112′, a laser-driving device 113′ of the transmitting interface 11′ in turns, then the data are transformed to an optical format by a laser diode 114′ and are transmitted to the receiving interface 13′ via the fiber 12′; after that, in the receiving interface 13′, the data are transformed to an optical current signal by a photodiode 131′ and further transformed to a current signal through a transimpedance amplifier (TIA) 132′ and a limiting amplifier 133′, then a clock and data recovery Circuit 134′ recovers the data and the clock thereof to clear signal; finally, the data are divided to multi data by a demux 135′ and transmitted to a second digital circuit 136′ for processing.

In the conventional optical communication system 1′, the clock and data recovery circuit 134′ can be a phase-locked loop circuit, referring to FIG. 2, the framework diagram of a phase-locked loop circuit is illustrated, as shown in FIG. 2, phase-locked loop circuit (the clock and data recovery circuit 134′) includes: a phase frequency detector 1341′, a charge pump circuit 1342′, a low pass filter 1343′, a voltage-controlled oscillator 1344′, a buffer 1345′, a first divider 1346′, and a divider chain 1347′, wherein the voltage-controlled oscillator 1344′, the buffer 1345′and the first divider 1346′ belong to high-speed operation circuits, which are the circuits causing mass current and power consumption in the clock and data recovery circuit 134′.

However, as the circuit is continuously operated under high temperature environment and causing, the power consumption per unit area must be strictly limited in an advanced integrated circuit chip with highly reduced circuit area for avoiding the circuit from faction fail and getting reliability problem. Thus, in the conventional optical communication system, the circuit area and the power consumption are very important when designing the integrated circuit of the voltage-controlled oscillator, the buffer and the first divider belonging to high-speed operation circuit.

Accordingly, in view of the whole circuit area and the power consumption of the voltage-controlled oscillator, the buffer and the first divider in the conventional optical communication system, the inventor of the present application has made great efforts to make inventive research thereon and eventually provided an integrated circuit capable of repeatedly using current.

### BRIEF SUMMARY OF THE INVENTION

The primary objective of the present invention is to provide an integrated circuit capable of repeatedly using current, in which an oscillator and a divider belonging to high frequency operation circuit of an optical communication system are integrated by one single driving current, so as to substantially reduce the whole circuit area and the power consumption of the oscillator and the divider.

Accordingly, to achieve the abovementioned primary objective, the inventor proposes an integrated circuit capable of repeatedly using current, comprising: a first differential input, which as an inverting amplifier and has a first input, a second input, a first output, and a second output;

a first cross couple pair, having a first couple input, a second couple input, and a first couple output, the first cross couple pair as an negative impedance of the first differential input by way of respectively connecting the first couple input and the second couple input to the first output and the second output;

a second differential input, which as the inverting amplifier and has a third input, a fourth input, a third output, and a fourth output;

a second cross couple pair, having a third couple input, a fourth couple input, and a second couple output, the second cross couple pair as the negative impedance of the second differential input by means of connecting the third couple input and the fourth couple input to the third output and the fourth output, respectively; and

a voltage-controlled oscillator, having a first oscillator input, a second oscillator input, a first oscillator output, and a second oscillator output, the first oscillator input and the second oscillator input respectively connect to the first couple output and the second couple output for coupling the voltage-controlled oscillator to the first cross couple pair and the second cross couple pair, so as to execute voltage-controlled oscillation of the signal outputted from the first cross couple pair and the second cross couple pair;

wherein a divider consists of the first differential input, the first cross couple pair, the second differential input, and the second cross couple pair, moreover, through the connection of the first differential input, the first cross couple pair, the second differential input, and the second cross couple pair, the divider and the voltage-controlled oscillator are driven by only one single current.

### BRIEF DESCRIPTION OF THE SEVERAL VIEWS OF THE DRAWINGS

The invention as well as a preferred mode of use and advantages thereof will be best understood by referring to the following detailed description of an illustrative embodiment in conjunction with the accompanying drawings, wherein:

FIG. 1 is a framework diagram of a conventional optical communication system;

FIG. 2 is the framework diagram of a phase-locked loop circuit;

FIG. 3 is the framework diagram of an integrated circuit capable of repeatedly using current according to the present invention;

FIG. 4 is a circuit diagram of the integrated circuit capable of repeatedly using current according to the present invention;

FIGS. 5A and 5B are output spectrum diagrams of the integrated circuit capable of repeatedly using current; and

FIGS. 6A and 6B are phase noise spectrum diagrams of the integrated circuit capable of repeatedly using current.

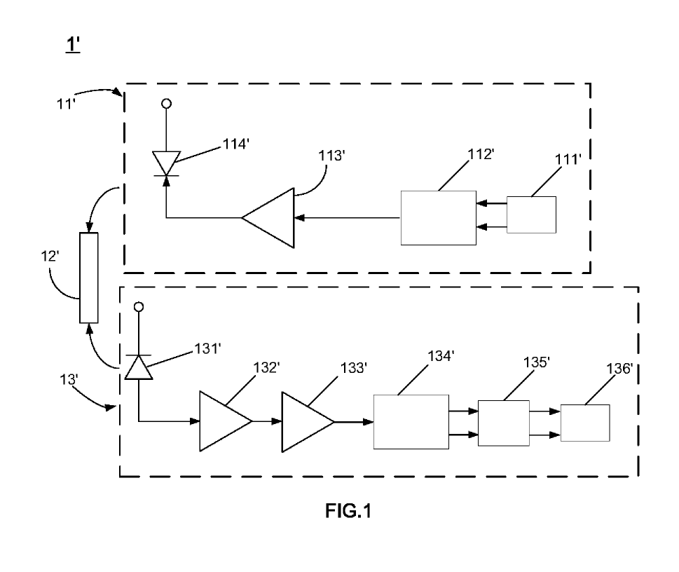

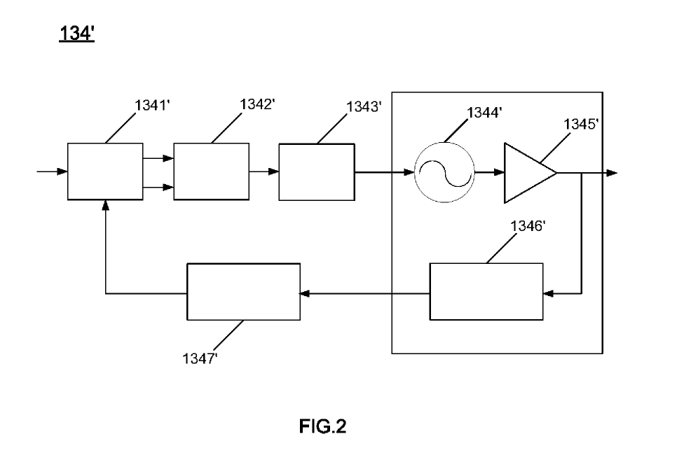

### DETAILED DESCRIPTION OF THE INVENTION

To more clearly describe an integrated circuit capable of repeatedly using current according to the present invention, embodiments of the present invention will be described in detail with reference to the attached drawings hereinafter.

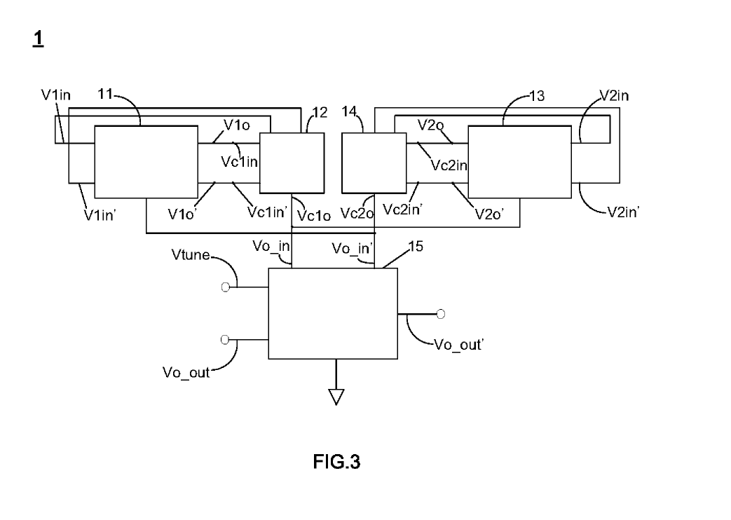

Referring to FIG. 3, a framework diagram of an integrated circuit capable of repeatedly using current according to the present invention is illustrated, as shown in FIG. 3, the integrated circuit 1 includes: a first differential input 11, a first cross couple pair 12, a second differential input 13, a second cross couple pair 14, and a voltage-controlled oscillator 15.

Continuously referring to FIG. 3, the first differential input 11 as an inverting amplifier and has a first input V1in, a second input V1in′, a first output V1o, and a second output V1o′. The first cross couple pair 12 has a first couple input Vc1in, a second couple input Vc1in′, and a first couple output Vc1o, and the first cross couple pair 12 as an negative impedance of the first differential input 11 by way of respectively connecting the first couple input Vc1in and the second couple input Vc1in′ to the first output V1o and the second output V1o′. The second differential input 13 as the inverting amplifier and has a third input V2in, a fourth input V2in′, a third output V2o, and a fourth output V2o′. The second cross couple pair 14 has a third couple input Vc2in, a fourth couple input Vc2in′, and a second couple output Vc2o, the second cross couple pair 14 as the negative impedance of the second differential input 13 by means of connecting the third couple input Vc2in and the fourth couple input Vc2in′ to the third output V2o and the fourth output V2o′, respectively. The voltage-controlled oscillator 15 has a first oscillator input Vo_in, a second oscillator input Vo_in′, a first oscillator output Vo_out, and a second oscillator output Vo_out′, the first oscillator input Vo_in and the second oscillator input Vo_in′ respectively connect to the first couple output Vc1o and the second couple output Vc2o for coupling the voltage-controlled oscillator 15 to the first cross couple pair 12 and the second cross couple pair 14, so as to execute voltage-controlled oscillation of the signal outputted from the first cross couple pair 12 and the second cross couple pair 14.

In the integrated circuit 1 described above, a divider consists of the first differential input 11, the first cross couple pair 12, the second differential input 13, and the second cross couple pair 14, moreover, through the connection of the first differential input 11, the first cross couple pair 12, the second differential input 13, and the second cross couple pair 14, the divider and the voltage-controlled oscillator 15 are driven by only one single current; furthermore, the first couple output Vc1o and the second couple output Vc2o respectively couple to the second input 13 and the first input 11 for forming a positive feedback.

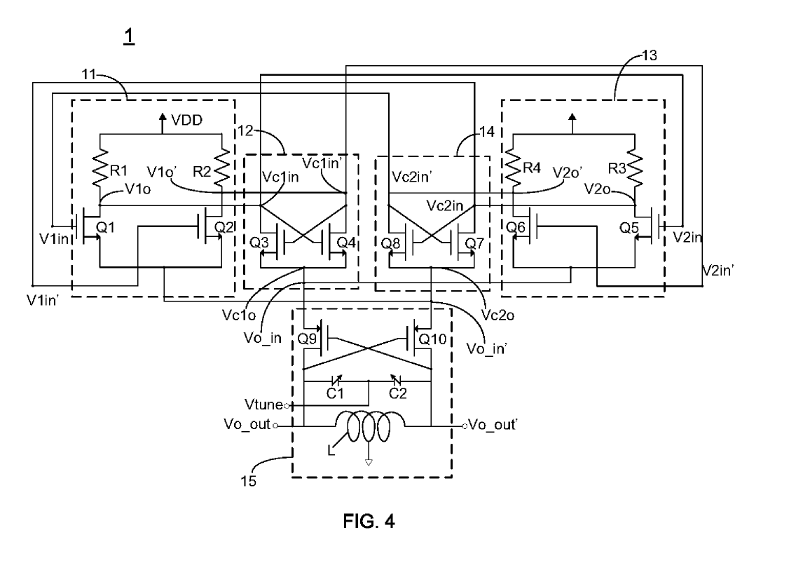

Please refer to FIG. 4, which illustrates a circuit diagram of the integrated circuit capable of repeatedly using current according to the present invention, as shown in FIG. 4, the first differential input 11 includes: a first transistor Q1, a first amplifying resistor R1, a second transistor Q2, and a second amplifying resistor R2, wherein the first amplifying resistor R1 as an amplifying resistor of the first transistor Q1. One terminal of the first amplifying resistor R1 couples to a drain terminal of the first transistor Q1 and another terminal thereof couples to a DC bias VDD. The second transistor Q2 connects to the first transistor in parallel Q1. The second amplifying resistor R2 as the amplifying resistor of the second transistor Q2. one terminal of the second amplifying resistor R2 couples to the drain terminal of the second transistor Q2 and another terminal thereof couples to the DC bias VDD.

Referring to FIGS. 3 and 4 together, a gate terminal of the first transistor Q1 is the first input V1in of the first differential input 11, the gate terminal of the second transistor Q2 is the second input V1in′ of the first differential input 11, and both a source terminal of the first transistor Q1 and the source terminal of the second transistor Q2 couple to the second couple output Vc2o. The first cross couple pair 12 further includes a third transistor Q3 and a fourth transistor Q4. Wherein the gate terminal of the third transistor Q3 connects to the drain terminal of the fourth transistor Q4, and the gate terminal of the fourth transistor Q4 connects to the drain terminal of the third transistor Q3, moreover, the drain terminals of the third transistor Q3 and the fourth transistor Q4 couple to each other.

Referring to FIG. 4 again, the second differential input 13 further includes: a fifth transistor Q3, a third amplifying resistor R3, a sixth transistor Q6, and a fourth amplifying resistor R4, wherein the third amplifying resistor R3 as the amplifying resistor of the fifth transistor Q5. One terminal of the third amplifying resistor R3 couples to the drain terminal of the fifth transistor Q5 and another terminal thereof couples to the DC bias VDD. The sixth transistor Q6 connects to the fifth transistor Q5 in parallel, and the fourth amplifying resistor R4 as the amplifying resistor of the sixth transistor Q6. One terminal of the fourth amplifying resistor R4 couples to the drain terminal of the sixth transistor Q6 and another terminal thereof couples to the DC bias VDD.

Please refer to FIGS. 3 and 4 again, the gate terminal of the fifth transistor Q2 is the third input V2in of the second differential input 13, the gate terminal of the sixth transistor Q6 is the fourth input V2in′ of the second differential input 13, and both the source terminals the fifth transistor Q5 and the sixth transistor Q6 couple to the first couple output Vc1o. Moreover, the second cross couple pair 14 further includes a seventh transistor Q7 and an eighth transistor Q8. The gate terminal of the seventh transistor Q7 connects to the drain terminal of the eighth transistor Q8, and the gate terminal of the eighth transistor Q8 connects to the drain terminal of the seventh transistor Q7, furthermore, the drain terminals of the seventh transistor Q7 and the eighth transistor Q8 couple to each other.

Continuously referring to FIG. 4, the voltage-controlled oscillator further includes: a ninth transistor Q9, a tenth transistor Q10, a first tuning capacitor C1, a second tuning capacitor C2, and an inductor L, wherein the tenth transistor Q10 couples to the drain terminal of the ninth transistor Q9 by the gate terminal thereof, and the gate terminal of the ninth transistor Q9 couples to the drain terminal of the tenth transistor Q10, so as to make the ninth transistor Q9 and the tenth transistor Q10 forming the negative resistor. One terminal of the first tuning capacitor C1 couples to the drain terminal of the ninth transistor Q9, and another terminal thereof couples to a tuning voltage Vtune. One terminal of the second tuning capacitor C2 couples to the drain terminal of the tenth transistor Q10, and another terminal thereof couples to the tuning voltage Vtune. One terminal of the inductor L couples to the drain terminal of the ninth transistor Q9 and another terminal thereof couples to drain terminal of the tenth transistor Q10, so that the inductor L forms two LC oscillators with the first tuning capacitor C1 and the second tuning capacitor C2. Thus, the LC tank of the LC oscillator induces an equivalent parallel resistance when the LC oscillator oscillates, and the equivalent parallel resistance may be offset by the negative formed by the ninth transistor Q9 and the tenth transistor Q10, so as to maintain the oscillation energy.

Moreover, in the above-mentioned voltage-controlled oscillator 15, it is able to adjust the capacitances of the first capacitor and the second capacitor via modulating the tuning voltage Vtune, so as to modulate the output oscillation frequency of the LC oscillators. Besides, the output of the voltage-controlled oscillator 15 not connecting any buffer amplifiers that makes the voltage-controlled oscillator 15 has a simple output load and suppresses the noise. As shown in FIG. 4, for the gate terminal of the first transistor Q1 is the first input V1in of the first differential input 11, the gate terminal of the first transistor Q1 couples to the drain terminal of the eighth transistor Q8, then a latch effect is formed. Similarly, for the gate terminal of the second transistor Q2 is the second input V1in′ of the first differential input 11, the gate terminal of the second transistor Q2 couples to the drain terminal of the seventh transistor Q7 and the latch effect is formed.

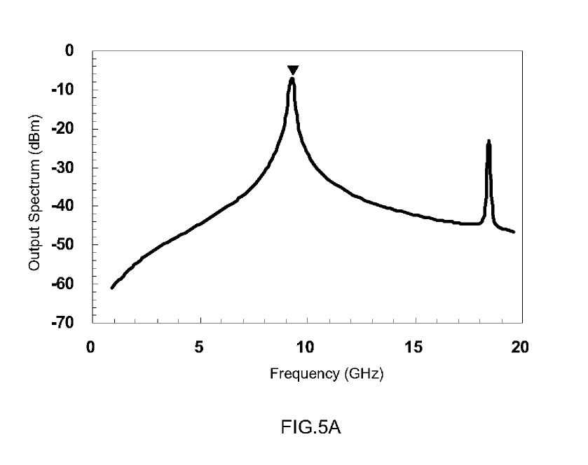

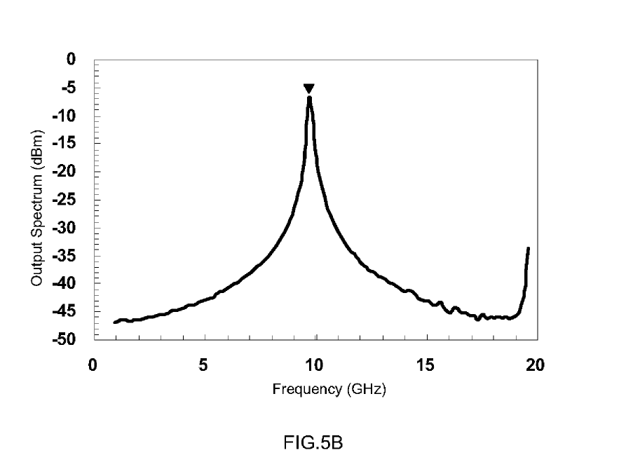

The integrated circuit 1 of the present invention integrates the divider and the voltage-controlled oscillator 15, so as to drive the divider by way of the single current of the voltage-controlled oscillator 15. In order to prove the practicability of the integrated circuit 1, a simulation software of high frequency circuit has been used, please refer to FIGS. 5A and 5B, output spectrum diagrams of the integrated circuit capable of repeatedly using current are illustrated. As shown in FIG. 5A, when the tuning voltage Vtune is 0V, the first oscillator output Vo_out outputs a first high frequency signal with a output power −7.5 dBm around frequency 9.313 GHz; Furthermore, As shown in FIG. 5B, when the tuning voltage Vtune is 1.8V, the first oscillator output Vo_out outputs the first high frequency signal with the output power −6.91 dBm around frequency 9.69 GHz.

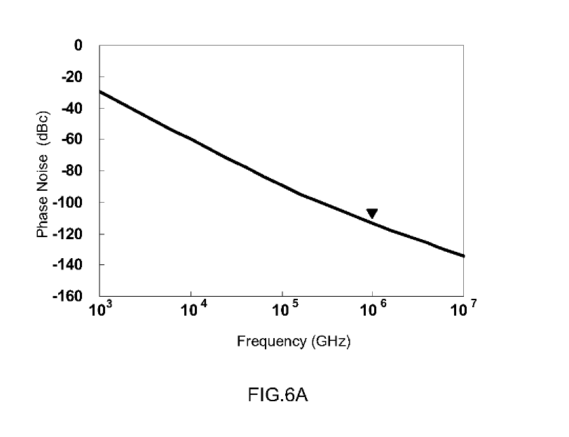

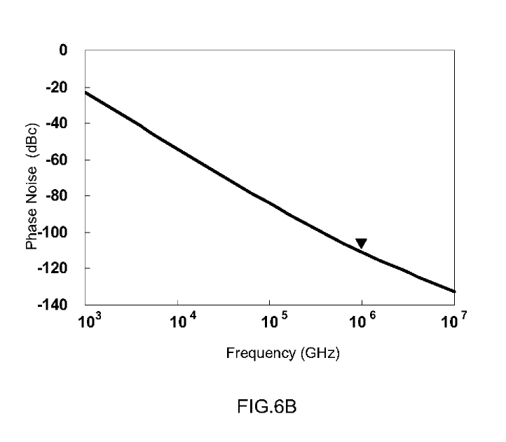

Referring to FIGS. 6A and 6B, phase noise spectrum diagrams of the integrated circuit capable of repeatedly using current are illustrated. As shown in FIG. 6A, when the tuning voltage Vtune is 0V, the integrated circuit 1 of the present invention induced a phase noise with a measurement value −113.458 dBc/Hz around frequency 1 MHz; Furthermore, As shown in FIG. 6B, when the tuning voltage Vtune is 1.8V, the integrated circuit 1 induced the phase noise with the measurement value −113.458 dBc/Hz around frequency 1 MHz. According to the above mention, it is easily to know that the integrated circuit 1 induces slight phase noise. Moreover, in a operation voltage 1.8V, the integrated circuit capable of repeatedly using current has a excellent simulation performance with the oscillator output frequency 9.3˜9.7 GHz, the power consumption 3.9 mW and the phase noise −113˜−110 dBc/Hz.

Thus, the integrated circuit capable of repeatedly using current of the present invention have been disclosed completely and clearly in the above description. In summary, the present invention has the following advantages:
1. The voltage-controlled oscillator and the divider belonging to high frequency operation circuit of an optical communication system are integrated by one single driving current, so as to substantially reduce the designed circuit area.
2. It just uses the DC bias and the tuning voltage in the integrated circuit of the present invention, and the transistors in the integrated circuit are not connected to other biases, for this reason, the area of inter-line is reduced so as to design the circuit layout easily and comfortably.
3. The voltage-controlled oscillator is made of merely one inductor and two tuning capacitors, so that the whole area of the integrated circuit is very small and capable of applying in SOC (system on chip).
4. The integrated circuit of the present invention is high-frequency operation but low power consumption and low phase noise.

The above description is made on embodiments of the present invention. However, the embodiments are not intended to limit scope of the present invention, and all equivalent implementations or alterations within the spirit of the present invention still fall within the scope of the present invention.

We claim:

1. An integrated circuit capable of repeatedly using current, comprising:
a first differential input, being as an inverting amplifier and having a first input, a second input, a first output, and a second output;
a first cross couple pair, having a first couple input, a second couple input, and a first couple output, the first cross couple pair being as an negative impedance of the first differential input by way of respectively connecting the first couple input and the second couple input to the first output and the second output;
a second differential input, being as the inverting amplifier and having a third input, a fourth input, a third output, and a fourth output;
a second cross couple pair, having a third couple input, a fourth couple input, and a second couple output, the second cross couple pair being as the negative impedance of the second differential input by means of connecting the third couple input and the fourth couple input to the third output and the fourth output, respectively; and
a voltage-controlled oscillator, having a first oscillator input, a second oscillator input, a first oscillator output, and a second oscillator output, the first oscillator input and the second oscillator input respectively connecting to the first couple output and the second couple output for coupling the voltage-controlled oscillator to the first cross couple pair and the second cross couple pair, so as to execute voltage-controlled oscillation of the signal outputted from the first cross couple pair and the second cross couple pair;
wherein a divider consists of the first differential input, the first cross couple pair, the second differential input, and the second cross couple pair, moreover, through the connection of the first differential input, the first cross couple pair, the second differential, and the second cross couple pair, the divider and the voltage-controlled oscillator being driven by only one single current.

2. The integrated circuit capable of repeatedly using current of claim 1, wherein the first differential input further comprises:
a first transistor;
a first amplifying resistor, being as an amplifying resistor of the first transistor, one terminal of the first amplifying resistor coupling to a drain terminal of the first transistor and another terminal thereof coupling to a DC bias;
a second transistor, connecting to the first transistor in parallel; and
a second amplifying resistor, being as the amplifying resistor of the second transistor, one terminal of the second amplifying resistor coupling to the drain terminal of the second transistor and another terminal thereof coupling to the DC bias.

3. The integrated circuit capable of repeatedly using current of claim 2, wherein a gate terminal of the first transistor is the first input of the first differential input, the gate terminal of the second transistor being the second input of the first differential input, and both a source terminal of the first transistor and the source terminal of the second transistor coupling to the second couple output.

4. The integrated circuit capable of repeatedly using current of claim 1, wherein the first cross couple pair further comprises a third transistor and a fourth transistor, a gate terminal of the third transistor connecting to a drain terminal of the fourth transistor, and the gate terminal of the fourth transistor connecting to the drain terminal of the third transistor, moreover, the drain terminals of the third transistor and the fourth transistor coupling to each other.

5. The integrated circuit capable of repeatedly using current of claim 1, wherein the second differential input further comprises:
a fifth transistor;
a third amplifying resistor, being as an amplifying resistor of the fifth transistor, one terminal of the third amplifying resistor coupling to a drain terminal of the fifth transistor and another terminal thereof coupling to a DC bias;
a sixth transistor, connecting to the fifth transistor in parallel; and
a fourth amplifying resistor, being as the amplifying resistor of the sixth transistor, one terminal of the fourth amplifying resistor coupling to the drain terminal of the sixth transistor and another terminal thereof coupling to the DC bias.

6. The integrated circuit capable of repeatedly using current of claim 5, wherein a gate terminal of the fifth transistor is the third input of the second differential input, the gate terminal of the sixth transistor is the fourth input of the second differential input, and both a source terminal of the fifth transistor and the source terminal of the sixth transistor coupling to the first couple output.

7. The integrated circuit capable of repeatedly using current of claim 1, wherein the second cross couple pair further comprises a seventh transistor and an eighth transistor, a gate terminal of the seventh transistor connecting to a drain terminal of the eighth transistor, and the gate terminal of the eighth transistor connecting to the drain terminal of the seventh transistor, moreover, the drain terminals of the seventh transistor and the eighth transistor coupling to each other.

8. The integrated circuit capable of repeatedly using current of claim 1, wherein the voltage-controlled oscillator further comprises:
a ninth transistor;
a tenth transistor, coupling to a drain terminal of the ninth transistor by a gate terminal thereof, and the gate terminal of the ninth transistor coupling to the drain terminal of the tenth transistor, so as to make the ninth transistor and the tenth transistor forming the negative resistor;
a first tuning capacitor, one terminal of the first tuning capacitor coupling to the drain terminal of the ninth transistor, and another terminal thereof coupling to a tuning voltage;
a second tuning capacitor, one terminal of the second tuning capacitor coupling to the drain terminal of the tenth transistor, and another terminal thereof coupling to the tuning voltage; and
an inductor, one terminal of the inductor coupling to the drain terminal of the ninth transistor and another terminal thereof coupling to drain terminal of the tenth transistor, the inductor being able to form two LC oscillators with the first tuning capacitor and the second tuning capacitor.

9. The integrated circuit capable of repeatedly using current of claim 8, wherein the capacitances of the first capacitor and the second capacitor can be adjusted by modulating the tuning voltage, so as to modulate the oscillating frequency of the LC oscillators.

10. The integrated circuit capable of repeatedly using current of claim 1, wherein the first couple output and the second couple output respectively couple to the second input and the first input for forming a positive feedback.
